(19) United States
(12) Patent Application Publication
(10) Pub. No.: US 2026/0095182 A1
(43) Pub. Date: Apr. 2, 2026

(54) HIGH SPEED LEVEL SHIFTER

(71) Applicant: Texas Instruments Incorporated, Dallas, TX (US)

(72) Inventors: Sneha Shetty, Bangalore (IN); Siddharth Gupta, Gurugram (IN); Sridhar Singhal, Noida (IN)

(21) Appl. No.: 18/902,747

(22) Filed: Sep. 30, 2024

(51) Int. Cl. H03K 19/0185

(52) U.S. Cl. CPC H03K 19/018507

(57) ABSTRACT

A semiconductor device includes a low voltage-to-high voltage level shifter. The level shifter is structured to receive a low voltage signal and output a high voltage signal. The level shifter includes a buffer structured to receive the low voltage input signal. The buffer includes a pullup transconductor, a pulldown transconductor, and a cutoff transconductor, coupled in series. The pullup transconductor has a negative transconductance and is structured to be controlled by the low voltage input signal. The pulldown transconductor has a positive transconductance and is structured to be controlled by the low voltage input signal The cutoff transconductor has a positive transconductance and is structured to be controlled by a delayed high voltage cutoff signal that inversely corresponds to the low voltage input signal.

### TECHNICAL FIELD

This disclosure relates to the field of semiconductor devices. More particularly, but not exclusively, this disclosure relates to level shifters in semiconductor devices.

### BACKGROUND

A semiconductor device may include a level shifter that accepts a digital input signal at a relatively low voltage and outputs a corresponding digital output signal at a higher voltage. The digital input signal may be produced by a low voltage circuit in the semiconductor device. The digital output signal may be provided to an output terminal of the semiconductor device.

### SUMMARY

A semiconductor device includes a low voltage-to-high voltage level shifter, hereinafter the level shifter. The level shifter is structured to receive a low voltage input signal and provide a high voltage output signal. The level shifter includes a buffer structured to receive the low voltage input signal. The buffer includes a pullup transconductor, a pulldown transconductor, and a cutoff transconductor, coupled in series. The pullup transconductor is structured to be controlled by the low voltage input signal. The pulldown transconductor is structured to be controlled by the low voltage input signal The cutoff transconductor is structured to be controlled by a delayed high voltage cutoff signal inversely corresponding to the low voltage input signal.

### BRIEF DESCRIPTION OF THE FIGURES

FIG. 1 is a diagram of a semiconductor device having an example level shifter.

FIG. 2A and FIG. 2B are schematic diagrams of another semiconductor device having an example level shifter.

FIG. 3 is a flowchart of a method of forming a semiconductor device having an example level shifter.

### DETAILED DESCRIPTION

The present disclosure is described with reference to the attached figures. The figures are not drawn to scale and they are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events are required to implement a methodology in accordance with the present disclosure.

A semiconductor device includes a level shifter structured to receive a low voltage input signal and provide a high voltage output signal that corresponds to the low voltage input signal. The low voltage input signal ranges from a reference potential, referred to herein as the reference potential VSS, to a low operating potential, referred to herein as the low operating potential VDD LO. The semiconductor device may include a low voltage digital logic circuit that operates from the reference potential VSS to the low operating potential VDD LO, which provides the low voltage input signal.

The high voltage output signal ranges from the reference potential VSS to a high operating potential, referred to herein as the high operating potential VDD HI. The high operating potential VDD HI is provided by a first power rail during operation of the semiconductor device. The low operating potential VDD LO is provided by a second power rail during operation of the semiconductor device. The reference potential VSS is provided by a reference power rail during operation of the semiconductor device. In some cases, the high voltage output signal may be provided to an output terminal of the semiconductor device, for communication with circuits that are external to the semiconductor device. In other cases, the high voltage output signal may be provided to a high voltage digital logic circuit that operates from the reference potential VSS to the high operating potential VDD HI. A ratio of the high operating potential VDD HI to the low operating potential VDD LO may range from 1.3 to 4.0. Commonly used nominal values for the high operating potential VDD HI are 5.0 volts and 3.3 volts. Tolerance ranges for the high operating potential VDD HI in many devices are +/−10 percent of the nominal value. Commonly used nominal values for the high operating potential VDD HI range from 3.3 volts down to 1.0 volt, with tolerances of +/−10 percent.

In this disclosure, a first signal may be disclosed as corresponding to a second signal. The first signal has a similar polarity as the second signal, that is, the first signal is high when the second signal is high, and the first signal is low when the second signal is low. Analogously, a third signal may be disclosed as inversely corresponding to a fourth signal. The third signal has an opposite polarity from the fourth signal, that is, the third signal is low when the fourth signal is high, and the third signal is high when the fourth signal is low. In both cases, transitions from low to high, and from high to low, in the first and third signals are delayed with respect to transitions in the second and fourth signals, respectively, by signal propagation through circuit elements generating the first and third signals.

The high voltage output signal corresponds to the low voltage input signal. During operation of the semiconductor device, when the low voltage input signal transitions from the reference potential VSS to the low operating potential VDD LO, the level shifter causes the high voltage output signal to transition from the reference potential VSS to the high operating potential VDD HI, and when the low voltage input signal transitions from the low operating potential VDD LO to the reference potential VSS, the level shifter causes the high voltage output signal to transition from the high operating potential VDD HI to the reference potential VSS.

A component such as a transconductor or a transistor that is disclosed as “structured to be controlled” by a signal has a control node connected to one or more circuits that provide the signal during operation of the corresponding semiconductor device. A control node may include a gate of a field effect transistor or a base of a bipolar junction transistor. Similarly, a component that is disclosed as “structured to receive” a signal has a control node connected to one or more circuits that provide the signal during operation of the corresponding semiconductor device. A component that is disclosed as “structured to provide” a signal is connected to one or more receiving elements, at a current node of the component. The receiving elements may be control nodes, such as a gates or bases, of transistors. A component that is disclosed as “structured to operate” between a first electric potential, such as the high operating potential VDD HI or the low operating potential VDD LO, and a second electric potential, such as the reference potential VSS, has a composition and architecture that enable the component to be operated with the first electric potential applied to a first current node of the component and the second electric potential applied to a second current node of the component. The first and second current nodes may be the source and drain of a field effect transistor, or the emitter and collector of a bipolar junction transistor. Transistors that are described as “high voltage” are structured to operate between the high operating potential VDD HI and the reference potential VSS, and transistors that are described as “low voltage” are structured to operate between the low operating potential VDD LO and the reference potential VSS. The high voltage transistors may have longer channel lengths than the low voltage transistors. The high voltage transistors may have thicker dielectric layers than the low voltage transistors. The high voltage transistors may have drift regions while the low voltage transistors are free of drift regions. The high voltage transistors may have other structural differences with respect to the low voltage transistors. The low voltage transistors may advantageously have higher switching speeds than the high voltage transistors, as a result of the shorter channel lengths.

Transducers and transistors are disclosed as in an ON state or in an OFF state. Transducers and transistors in the ON state have lower impedances that in the OFF state, and thus may conduct more current than in the OFF state.

A component that is disclosed as coupled to, or connected to, another component or a potential, such as the high operating potential VDD HI, is structured to support direct current (DC) through the connection, between the component and the other component or the potential. Aspects of this disclosure which describe current flows and signal voltage transitions are related to operation of the semiconductor device. The current flows and signal voltage transitions are explained to assist understanding of the semiconductor device. Current flows and signal voltage transitions may not be present in the semiconductor device when the semiconductor device is not powered. A component that is disclosed as connected to an operating potential or a reference potential, or connected between an operating potential and a reference potential, is connected to one or more conductive elements of the semiconductor device that are structured to provide the potential(s) during operation of the semiconductor device.

One or more operational characteristics of various circuits, systems and/or components are hereinafter described in the context of functions which in some cases result from configuration and/or interconnection of various structures when circuitry is powered and operating. Various disclosed structures and methods of the present disclosure may be beneficially applied to manufactured electronic apparatus such as an integrated circuit. While such examples may be expected to provide various improvements, no particular result is a requirement of the present disclosure unless explicitly recited in a particular claim.

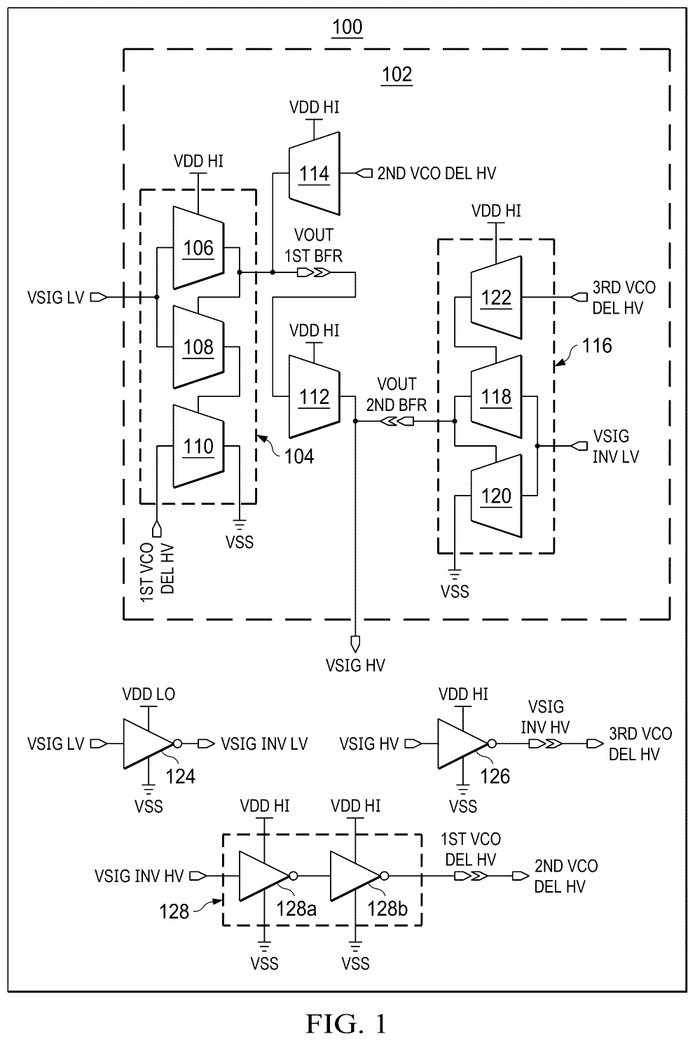

FIG. 1 is a diagram of a semiconductor device having an example level shifter. The semiconductor device 100 may be manifested as an integrated circuit, a micro-electro-mechanical system (MEMS) device, an electro-optical device, a microfluidic device, or a micro-optical-mechanical device, by way of example. The semiconductor device 100 includes the level shifter 102. The level shifter 102 is structured to receive a low voltage input signal VSIG LV, labeled “VSIG LV” in FIG. 1, that ranges from a reference potential VSS, labeled “VSS” in FIG. 1, provided by a reference power rail of the semiconductor device 100, to a low operating potential VDD LO, labeled “VDD LO” in FIG. 1, provided by a second power rail of the semiconductor device 100. The level shifter 102 is structured to provide a high voltage output signal VSIG HV, labeled “VSIG HV” in FIG. 1, that ranges from the reference potential VSS to a high operating potential VDD HI, labeled “VDD HI” in FIG. 1, provided by a first power rail of the semiconductor device 100. The high operating potential VDD HI is higher than the low operating potential VDD LO. The high voltage output signal VSIG HV corresponds to the low voltage input signal VSIG LV after a delay of signal propagation through the level shifter 102.

The level shifter 102 includes a first buffer 104. The first buffer 104 is structured to receive the low voltage input signal VSIG LV as an input. The first buffer 104 includes a first pullup transconductor 106 structured to be controlled by the low voltage input signal VSIG LV. In this example, the first pullup transconductor 106 is connected to the high operating potential VDD HI, as indicated in FIG. 1. The first pullup transconductor 106 may be manifested as a single high voltage transistor structured to operate between the high operating potential VDD HI and the reference potential VSS, such as a metal oxide semiconductor (MOS) transistor, a drain extended MOS (DEMOS) transistor, a junction field effect transistor (JFET), or a bipolar junction transistor (BJT), by way of example. The first pullup transconductor 106 may be manifested by two or more transistors, structured to operate between the high operating potential VDD HI and the reference potential VSS, for example, in a cascode configuration. Current from the high operating potential VDD HI through the first pullup transconductor 106 to an output of the first pullup transconductor 106 is controlled, that is, modulated, by the low voltage input signal VSIG LV. In this example, the first pullup transconductor 106 has a negative transconductance; the current through the first pullup transconductor 106 is reduced when the low voltage input signal VSIG LV increases in amplitude, and the current through the first pullup transconductor 106 is increased when the low voltage input signal VSIG LV decreases in amplitude.

The first buffer 104 includes a first pulldown transconductor 108 structured to be controlled by the low voltage input signal VSIG LV. In this example, the first pulldown transconductor 108 is connected to the output of the first pullup transconductor 106, as indicated in FIG. 1. The first pulldown transconductor 108 may be manifested as a single high voltage transistor, or by two or more transistors, structured to operate between the high operating potential VDD HI and the reference potential VSS. Current from the first pullup transconductor 106 through the first pulldown transconductor 108 is controlled by the low voltage input signal VSIG LV. In this example, the first pulldown transconductor 108 has a positive transconductance; the current through the first pulldown transconductor 108 is increased when the low voltage input signal VSIG LV increases in amplitude, and is decreased when the low voltage input signal VSIG LV decreases in amplitude.

The first buffer 104 includes a first cutoff transconductor 110. The first cutoff transconductor 110 is structured to be controlled by a first delayed high voltage cutoff signal 1st VCO DEL HV, labeled “1st VCO DEL HV” in FIG. 1. The first delayed high voltage cutoff signal 1st VCO DEL HV inversely corresponds to the low voltage input signal, that is, when the low voltage input signal VSIG LV transitions from the reference potential VSS to the low operating potential VDD LO, the semiconductor device 100 causes the first delayed high voltage cutoff signal 1st VCO DEL HV to transition from the high operating potential VDD HI to the reference potential VSS after a delay of one or more logic gates, and when the low voltage input signal VSIG LV transitions from the low operating potential VDD LO to the reference potential VSS, the semiconductor device 100 causes the first delayed high voltage cutoff signal 1st VCO DEL HV to transition from the reference potential VSS to the high operating potential VDD HI after a delay of one or more logic gates. In this example, the first cutoff transconductor 110 is connected to an output of the first pulldown transconductor 108, as indicated in FIG. 1. An output of the first cutoff transconductor 110 is connected to the reference potential VSS, as indicated in FIG. 1. The first cutoff transconductor 110 may be manifested as a single high voltage transistor, or by two or more transistors, structured to operate between the high operating potential VDD HI and the reference potential VSS. Current from the first pulldown transconductor 108 through the first cutoff transconductor 110 is controlled by the first delayed high voltage cutoff signal 1st VCO DEL HV. In this example, the first cutoff transconductor 110 has a positive transconductance.

The output of the first pullup transconductor 106 is connected to an output VOUT 1st BFR, labeled “VOUT 1st BFR” in FIG. 1, of the first buffer 104. The output VOUT 1st BFR provides a voltage to other circuit elements of the semiconductor device 100, while current through the output VOUT 1st BFR is less than the current from the first pullup transconductor 106 to the first pulldown transconductor 108.

The level shifter 102 includes a rising edge pullup transconductor 112 connected to the high operating potential VDD HI. The output VOUT 1st BFR of the first buffer 104 is connected to an input of the rising edge pullup transconductor 112. The rising edge pullup transconductor 112 is structured to be controlled by the output of the first buffer 104. An output of the rising edge pullup transconductor 112 is connected to the high voltage output signal VSIG HV of the level shifter 102. In this example, the rising edge pullup transconductor 112 has a negative transconductance.

The level shifter 102 includes a reset transconductor 114 connected to the high operating potential VDD HI. The reset transconductor 114 is structured to be controlled by a second delayed high voltage cutoff signal 2nd VCO DEL HV, labeled “2nd VCO DEL HV” in FIG. 1. The second delayed high voltage cutoff signal 2nd VCO DEL HV ranges from the reference potential VSS to the high operating potential VDD HI, and inversely corresponds to the low voltage input signal VSIG LV after a delay of one or more logic gates. An output of the reset transconductor 114 is connected to the output VOUT 1st BFR of the first buffer 104. In this example, the reset transconductor 114 has a negative transconductance.

The level shifter 102 includes a second buffer 116. The second buffer 116 is structured to receive an inverted low voltage signal VSIG INV LV as an input. The inverted low voltage signal VSIG INV LV is labeled “VSIG INV LV” in FIG. 1, and inversely corresponds to the low voltage input signal VSIG LV after a delay of one or more logic gates. The inverted low voltage signal VSIG INV LV ranges from the reference potential VSS to the low operating potential VDD LO.

The second buffer 116 includes a second cutoff transconductor 122. The second cutoff transconductor 122 is structured to be controlled by a third delayed high voltage cutoff signal 3rd VCO DEL HV, labeled “3rd VCO DEL HV” in FIG. 1. The third delayed high voltage cutoff signal 3rd VCO DEL HV ranges from the reference potential VSS to the high operating potential VDD HI, and inversely corresponds to the low voltage input signal VSIG LV after a delay of one or more logic gates. The second cutoff transconductor 122 may be manifested as a single high voltage transistor, or by two or more transistors, structured to operate between the high operating potential VDD HI and the reference potential VSS. In this example, the second cutoff transconductor 122 has a negative transconductance.

The second buffer 116 includes a second pullup transconductor 118 structured to be controlled by the inverted low voltage signal VSIG INV LV. In this example, the second pullup transconductor 118 is connected to an output of the second cutoff transconductor 122, as indicated in FIG. 1. The second pullup transconductor 118 may be manifested as any of the examples disclosed for the first pullup transconductor 106. In this example, the second pullup transconductor 118 has a negative transconductance.

The second buffer 116 includes a second pulldown transconductor 120 structured to be controlled by the inverted low voltage signal VSIG INV LV. In this example, the second pulldown transconductor 120 is coupled between the output of the second pullup transconductor 118 and the reference potential VSS, as indicated in FIG. 1. The second pulldown transconductor 120 may be manifested as a single high voltage transistor, or by two or more transistors, structured to operate between the high operating potential VDD HI and the reference potential VSS. In this example, the second pulldown transconductor 120 has a positive transconductance.

The output of the second pullup transconductor 118 is connected to an output VOUT 2nd BFR, labeled “VOUT 2nd BFR” in FIG. 1, of the second buffer 116. The output VOUT 2nd BFR is connected to the high voltage output signal VSIG HV of the level shifter 102. The output VOUT 2nd BFR provides a voltage to other circuit elements of the semiconductor device 100, while current through the output VOUT 2nd BFR is less than the current from the second pullup transconductor 118 to the second pulldown transconductor 120.

The semiconductor device 100 of this example further includes a low voltage inverter 124. The low voltage inverter 124 is connected between the low operating potential VDD LO and the reference potential VSS. The low voltage inverter 124 is structured to be controlled by the low voltage input signal VSIG LV. The low voltage inverter 124 is structured to provide an inverted low voltage signal VSIG INV LV, labeled “VSIG INV LV” in FIG. 1. The inverted low voltage signal VSIG INV LV ranges from the reference potential VSS to the low operating potential VDD LO, and inversely corresponds to the low voltage input signal VSIG LV after a delay of signal propagation through the low voltage inverter 124. The low voltage inverter 124 may include low voltage transistors. The low voltage inverter 124 may be free of high voltage transistors, which may advantageously reduce the delay of signal propagation through the low voltage inverter 124 compared to an inverter having high voltage transistors. The low voltage inverter 124 eliminates need for a high voltage-to-low voltage level shifter to provide the inverted low voltage signal VSIG INV LV, advantageously reducing an area of the semiconductor device 100.

The semiconductor device 100 of this example further includes a high voltage inverter 126. The high voltage inverter 126 is connected between the high operating potential VDD HI and the reference potential VSS. The high voltage inverter 126 is structured to be controlled by the high voltage output signal VSIG HV. The high voltage inverter 126 is structured to provide an inverted high voltage signal VSIG INV HV, labeled “VSIG INV HV” in FIG. 1. The inverted high voltage signal VSIG INV HV ranges from the reference potential VSS to the high operating potential VDD HI, and inversely corresponds to the high voltage output signal VSIG HV after a delay of signal propagation through the high voltage inverter 126. The high voltage inverter 126 may include high voltage transistors, structured to operate between the high operating potential VDD HI and the reference potential VSS. The high voltage inverter 126 may be free of low voltage transistors, advantageously reducing an area of the high voltage inverter 126.

The semiconductor device 100 of this example further includes a high voltage delay buffer 128 structured to receive the inverted high voltage signal VSIG INV HV and provide the first delayed high voltage cutoff signal 1st VCO DEL HV and the second delayed high voltage cutoff signal 2nd VCO DEL HV, as indicated in FIG. 1. The high voltage delay buffer 128 may include two delay stages. By way of example, the high voltage delay buffer 128 may include a first high voltage inverter 128a and a second high voltage inverter 128b, both operating between the high operating potential VDD HI and the reference potential VSS, as indicated in FIG. 1. The first high voltage inverter 128a may be structured to be controlled by the inverted high voltage signal VSIG INV HV. The second high voltage inverter 128b may be structured to be controlled by an output of the first high voltage inverter 128a. An output of the second high voltage inverter 128b may provide the first delayed high voltage cutoff signal 1st VCO DEL HV and the second delayed high voltage cutoff signal 2nd VCO DEL HV. Other circuit configurations for the high voltage delay buffer 128 are within the scope of this example. In other versions of this example, the high voltage delay buffer 128 may be structured to receive the high voltage output signal VSIG HV. In such versions, the high voltage delay buffer 128 may include one or three high voltage inverters connected sequentially. The high voltage delay buffer 128 may include high voltage transistors, structured to operate between the high operating potential VDD HI and the reference potential VSS. The high voltage delay buffer 128 may be free of low voltage transistors, advantageously reducing an area of the high voltage delay buffer 128.

Operation of the semiconductor device 100 includes a rising edge transition of the low voltage input signal VSIG LV, that is, a transition of the low voltage input signal VSIG LV from the reference potential VSS to the low operating potential VDD LO. Operation of the semiconductor device 100 also includes a falling edge transition of the low voltage input signal VSIG LV, that is, a transition of the low voltage input signal VSIG LV from the low operating potential VDD LO to the reference potential VSS. Operation of the semiconductor device 100 through the rising edge transition and the falling edge transition is disclosed in reference to FIG. 1.

Immediately before the rising edge transition, the low voltage input signal VSIG LV is at the reference potential VSS, causing the first pullup transconductor 106 to be in an ON state and causing the first pulldown transconductor 108 to be in an OFF state. The first pullup transconductor 106 in the ON state and the first pulldown transconductor 108 in the OFF state causes the output VOUT 1st BFR of the first buffer 104 to be at the high operating potential VDD HI. The output VOUT 1st BFR of the first buffer 104 at the high operating potential VDD HI causes the rising edge pullup transconductor 112 to be in an OFF state.

Immediately before the rising edge transition, the inverted low voltage signal VSIG INV LV is at the low operating potential VDD LO, by operation of the low voltage inverter 124. The inverted low voltage signal VSIG INV LV at the low operating potential VDD LO causes the second pullup transconductor 118 to be in an OFF state or a near OFF state and causes the second pulldown transconductor 120 to be in an ON state or a partial ON state, which causes the output VOUT 2nd BFR of the second buffer 116 to be at the reference potential VSS. In the near OFF state, the second pullup transconductor 118 has a lower impedance than the OFF state, but a higher impedance than an ON state for the second pullup transconductor 118. In the partial ON state, the second pulldown transconductor 120 has a higher impedance than the ON state, but a lower impedance than an OFF state for the second pulldown transconductor 120.

Immediately before the rising edge transition, the rising edge pullup transconductor 112 in the OFF state and the output VOUT 2nd BFR of the second buffer 116 at the reference potential VSS causes the high voltage output signal VSIG HV to be at the reference potential VSS. The high voltage output signal VSIG HV at the reference potential VSS causes the inverted high voltage signal VSIG INV HV and the third delayed high voltage cutoff signal 3rd VCO DEL HV to be at the high operating potential VDD HI, by operation of the high voltage inverter 126. The inverted high voltage signal VSIG INV HV at the high operating potential VDD HI causes the first delayed high voltage cutoff signal 1st VCO DEL HV and the second delayed high voltage cutoff signal 2nd VCO DEL HV to be at the high operating potential VDD HI, by operation of the high voltage delay buffer 128. The first delayed high voltage cutoff signal 1st VCO DEL HV at the high operating potential VDD HI causes the first cutoff transconductor 110 to be in an ON state. The second delayed high voltage cutoff signal 2nd VCO DEL HV at the high operating potential VDD HI causes the reset transconductor 114 to be in an OFF state. The third delayed high voltage cutoff signal 3rd VCO DEL HV at the high operating potential VDD HI causes the second cutoff transconductor 122 to be in an OFF state, increasing a total impedance between the output VOUT 2nd BFR of the second buffer 116 and the high operating potential VDD HI.

When the low voltage input signal VSIG LV executes the rising edge transition, the low voltage input signal VSIG LV transitions from the reference potential VSS to the low operating potential VDD LO. The rising edge transition causes the low voltage inverter 124 to transition the inverted low voltage signal VSIG INV LV from the low operating potential VDD LO to the reference potential VSS.

In the first buffer 104, the low voltage input signal VSIG LV transitioning to the low operating potential VDD LO causes the first pullup transconductor 106 to transition to an OFF state or a near OFF state, and causes the first pulldown transconductor 108 to transition to an ON state or a partial ON state. The first cutoff transconductor 110 in the ON state, the first pullup transconductor 106 transitioning to the OFF state or the near OFF state, and the first pulldown transconductor 108 transitioning to the ON state or the partial ON state causes the output VOUT 1st BFR of the first buffer 104 to transition to the reference potential VSS. Having the first pulldown transconductor 108 connected to the output of the first pullup transconductor 106, and having the first cutoff transconductor 110 connected between the output of the first pulldown transconductor 108 and the reference potential VSS, may reduce a charge required to be transferred through the first pulldown transconductor 108 during the rising edge transition, advantageously enabling a higher speed transition of the output VOUT 1st BFR of the first buffer 104 to the reference potential VSS.

The second pulldown transconductor 120 transitions to the OFF state, isolating the output VOUT 1st BFR of the first buffer 104 from the reference potential VSS through the second pulldown transconductor 120. The output VOUT 1st BFR transitioning to the reference potential VSS causes the rising edge pullup transconductor 112 to transition to an ON state, which causes the output of the rising edge pullup transconductor 112 to transition from the reference potential VSS to the high operating potential VDD HI. Having the level shifter 102 configured with the output VOUT 1st BFR connected to a single input node, namely the input of the rising edge pullup transconductor 112, may advantageously improve a speed of the first buffer 104, compared with buffers having outputs driving two or more inputs.

In the second buffer 116, the inverted low voltage signal VSIG INV LV transitioning to the reference potential VSS causes the second pullup transconductor 118 to transition to an ON state, and causes the second pulldown transconductor 120 to transition to an OFF state. The second cutoff transconductor 122 in the OFF state and the second pulldown transconductor 120 transitioning to the OFF state causes the second buffer 116 to present a high impedance at the output VOUT 2nd BFR of the second buffer 116. Thus, the high voltage output signal VSIG HV of the level shifter 102 is driven by the output of the rising edge pullup transconductor 112 to transition from the reference potential VSS to the high operating potential VDD HI.

The high voltage output signal VSIG HV transitioning to the high operating potential VDD HI causes the inverted high voltage signal VSIG INV HV and the third delayed high voltage cutoff signal 3rd VCO DEL HV to transition to the reference potential VSS, by operation of the high voltage inverter 126. The third delayed high voltage cutoff signal 3rd VCO DEL HV transitioning to the reference potential VSS causes the second cutoff transconductor 122 to transition to an ON state. The second cutoff transconductor 122 and the second pullup transconductor 118 both in ON states and the second pulldown transconductor 120 in the OFF state causes the output VOUT 2nd BFR of the second buffer 116 to transition to the high operating potential VDD HI, reinforcing the output of the rising edge pullup transconductor 112.

The inverted high voltage signal VSIG INV HV transitioning to the reference potential VSS causes the first delayed high voltage cutoff signal 1st VCO DEL HV and the second delayed high voltage cutoff signal 2nd VCO DEL HV to transition to the reference potential VSS, by operation of the high voltage delay buffer 128, after a delay of signal propagation through the high voltage delay buffer 128. The second delayed high voltage cutoff signal 2nd VCO DEL HV transitioning to the reference potential VSS causes the reset transconductor 114 to transition to an ON state, which causes the output of the reset transconductor 114 to transition to the high operating potential VDD HI, which in turn causes the rising edge pullup transconductor 112 to transition to the OFF state, isolating the high voltage output signal VSIG HV of the level shifter 102 from the high operating potential VDD HI through the rising edge pullup transconductor 112.

The first delayed high voltage cutoff signal 1st VCO DEL HV transitioning to the reference potential VSS causes the first cutoff transconductor 110 to transition to an OFF state, which advantageously reduces current through the first pulldown transconductor 108. The output of the reset transconductor 114 transitioning to the high operating potential VDD HI, in combination with the first cutoff transconductor 110 transitioning to the OFF state, advantageously resets the output VOUT 1st BFR of the first buffer 104 to the high operating potential VDD HI, to be ready for the next rising edge transition in the low voltage input signal VSIG LV.

When the low voltage input signal VSIG LV executes the falling edge transition, the low voltage input signal VSIG LV transitions from the low operating potential VDD LO to the reference potential VSS. The falling edge transition causes the low voltage inverter 124 to transition the inverted low voltage signal VSIG INV LV from the reference potential VSS to the low operating potential VDD LO.

In the first buffer 104, the low voltage input signal VSIG LV transitioning to the reference potential VSS causes the first pullup transconductor 106 to transition to the ON state, and causes the first pulldown transconductor 108 to transition to the OFF state. The first cutoff transconductor 110 in the OFF state, the first pullup transconductor 106 transitioning to the ON state, and the first pulldown transconductor 108 transitioning to the OFF state maintains the output VOUT 1st BFR of the first buffer 104 at the high operating potential VDD HI.

In the second buffer 116, the inverted low voltage signal VSIG INV LV transitioning to the low operating potential VDD LO causes the second pullup transconductor 118 to transition to the OFF state or the near OFF state and causes the second pulldown transconductor 120 to transition to the ON state or the partial ON state. The second cutoff transconductor 122 is in the ON state, because the third delayed high voltage cutoff signal 3rd VCO DEL HV is at the reference potential VSS by operation of the high voltage inverter 126. The second cutoff transconductor 122 in the ON state, the second pullup transconductor 118 transitioning to the OFF state or the near OFF state, and the second pulldown transconductor 120 transitioning to the ON state or the partial ON state causes the output VOUT 2nd BFR of the second buffer 116 to transition to the reference potential VSS.

The output VOUT 1st BFR of the first buffer 104 at the high operating potential VDD HI maintains the rising edge pullup transconductor 112 in the OFF state, thus maintaining isolation of the high voltage output signal VSIG HV of the level shifter 102 through the rising edge pullup transconductor 112. The high voltage output signal VSIG HV of the level shifter 102 is thus driven by the output VOUT 2nd BFR of the second buffer 116 to transition to the reference potential VSS.

The high voltage output signal VSIG HV transitioning to the reference potential VSS causes the inverted high voltage signal VSIG INV HV and the third delayed high voltage cutoff signal 3rd VCO DEL HV to transition to the high operating potential VDD HI, by operation of the high voltage inverter 126. The third delayed high voltage cutoff signal 3rd VCO DEL HV transitioning to the high operating potential VDD HI causes the second cutoff transconductor 122 to transition to the OFF state. The second cutoff transconductor 122 in the OFF state, the second pullup transconductor 118 in the OFF state or the near OFF state, and the second pulldown transconductor 120 in the ON state stabilizes the output VOUT 2nd BFR of the second buffer 116 at the reference potential VSS.

The inverted high voltage signal VSIG INV HV transitioning to the high operating potential VDD HI causes the first delayed high voltage cutoff signal 1st VCO DEL HV and the second delayed high voltage cutoff signal 2nd VCO DEL HV to transition to the high operating potential VDD HI, by operation of the high voltage delay buffer 128, after a delay of signal propagation through the high voltage delay buffer 128. The second delayed high voltage cutoff signal 2nd VCO DEL HV transitioning to the high operating potential VDD HI causes the reset transconductor 114 to transition to an OFF state, which provides a high impedance to the output VOUT 1st BFR of the first buffer 104, enabling a subsequent rising edge transition in the low voltage input signal VSIG LV.

The first delayed high voltage cutoff signal 1st VCO DEL HV transitioning to the high operating potential VDD HI causes the first cutoff transconductor 110 to transition to an ON state, enabling a subsequent rising edge transition in the low voltage input signal VSIG LV.

In alternate versions of this example, the high voltage delay buffer 128 may include more than two logic gates in its signal propagation path. In alternate versions of this example, the first cutoff transconductor 110 may be connected between the first pullup transconductor 106 and the first pulldown transconductor 108. In alternate versions of this example, the second cutoff transconductor 122 may be connected between the second pullup transconductor 118 and the second pulldown transconductor 120.

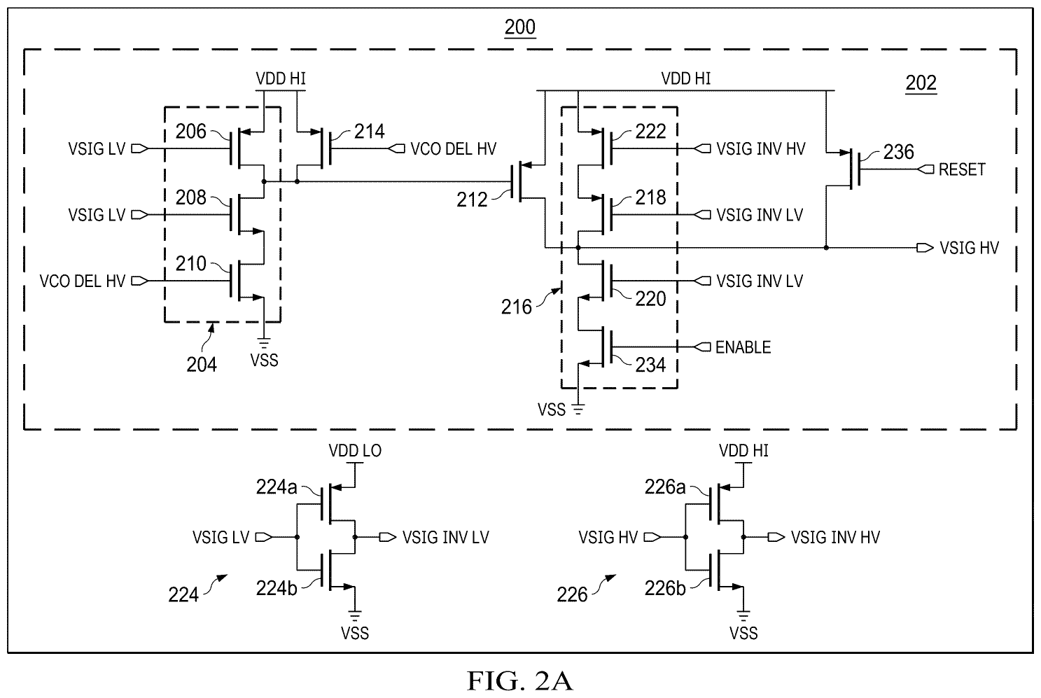

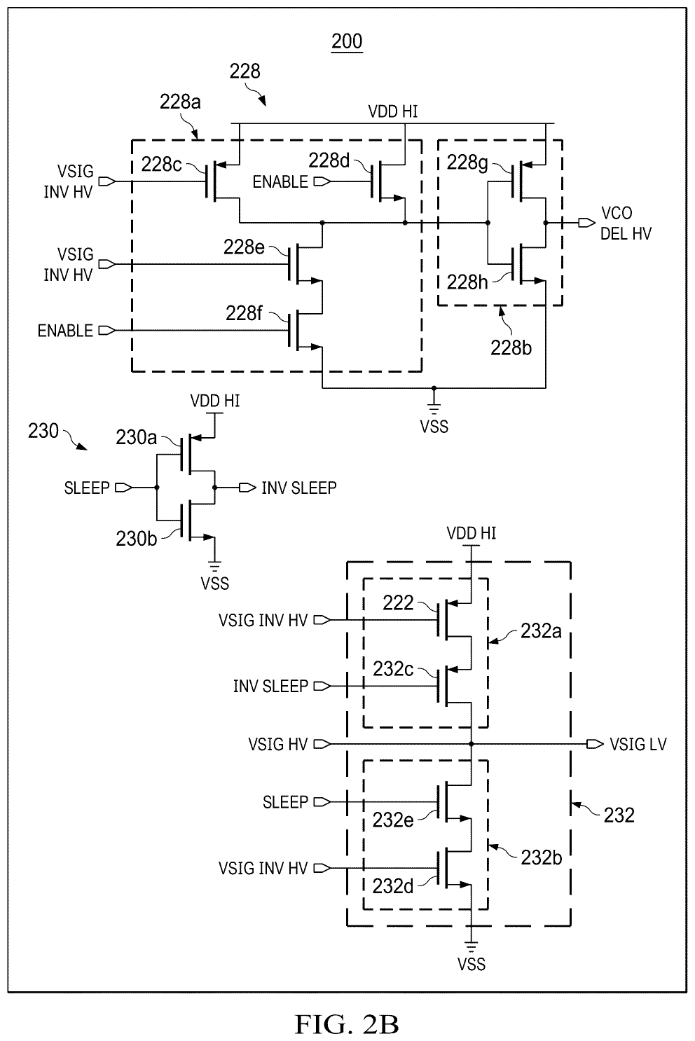

FIG. 2A and FIG. 2B are schematic diagrams of another semiconductor device having an example level shifter. The semiconductor device 200 may be manifested as any of the device types disclosed in reference to the semiconductor device 100 of FIG. 1. The semiconductor device 200 includes the level shifter 202. The level shifter 202 is structured to receive a low voltage input signal VSIG LV, labeled “VSIG LV” in FIG. 2A, that ranges from a reference potential VSS to a low operating potential VDD LO, labeled “VSS” and “VDD LO” in FIG. 2A, respectively. The level shifter 202 is structured to provide a high voltage output signal VSIG HV, labeled “VSIG HV” in FIG. 2A and FIG. 2B, that ranges from the reference potential VSS to a high operating potential VDD HI, labeled “VDD HI” in FIG. 2A and FIG. 2B. The high operating potential VDD HI is higher than the low operating potential VDD LO. The high voltage output signal VSIG HV corresponds to the low voltage input signal VSIG LV after a delay of signal propagation through the level shifter 202.

Transistors in the semiconductor device 200 are disclosed as p-channel metal oxide semiconductor (PMOS) transistors and n-channel metal oxide semiconductor (NMOS) transistors. The PMOS and NMOS transistors in this example are enhancement mode transistors.

The level shifter 202 includes a first buffer 204 which is structured to receive the low voltage input signal VSIG LV as an input. The first buffer 204 includes a first pullup PMOS transistor 206, a first pulldown NMOS transistor 208, and a first cutoff NMOS transistor 210, connected in series between the high operating potential VDD HI and the reference potential VSS. The first pullup PMOS transistor 206 and the first pulldown NMOS transistor 208 are structured to be controlled by the low voltage input signal VSIG LV, that is, gates of the first pullup PMOS transistor 206 and the first pulldown NMOS transistor 208 are connected to a circuit, not specifically shown, that is structured to provide the low voltage input signal VSIG LV. The first cutoff NMOS transistor 210 is structured to be controlled by a delayed high voltage cutoff signal VCO DEL HV, labeled “VCO DEL HV” in FIG. 2A and FIG. 2B. The delayed high voltage cutoff signal VCO DEL HV inversely corresponds to the low voltage input signal VSIG LV, after a delay of signal propagation through the level shifter 202, a high voltage inverter 226, and the high voltage delay buffer 228. A gate of the first cutoff NMOS transistor 210 is connected to an output of the high voltage delay buffer 228. A drain of the first pullup PMOS transistor 206 is connected to a drain of the first pulldown NMOS transistor 208; the drains of the first pullup PMOS transistor 206 and the first pulldown NMOS transistor 208 provide an output of the first buffer 204. The output of the first buffer 204 provides a voltage to other circuit elements of the semiconductor device 200, while current through the output of the first buffer 204 is less than the current from the first pullup PMOS transistor 206 to the first pulldown NMOS transistor 208.

The level shifter 202 includes a rising edge pullup PMOS transistor 212 connected to the high operating potential VDD HI. The rising edge pullup PMOS transistor 212 is structured to be controlled by the output of the first buffer 204, that is, a gate of the rising edge pullup PMOS transistor 212 is connected to the drains of the first pullup PMOS transistor 206 and the first pulldown NMOS transistor 208. A drain of the rising edge pullup PMOS transistor 212 is connected to the high voltage output signal VSIG HV of the level shifter 202.

The level shifter 202 includes a reset PMOS transistor 214 connected to the high operating potential VDD HI. The reset PMOS transistor 214 is structured to be controlled by the delayed high voltage cutoff signal VCO DEL HV. A drain of the reset PMOS transistor 214 is connected to the drain of the first pullup PMOS transistor 206.

The semiconductor device 200 of this example includes a low voltage inverter 224. The low voltage inverter 224 is structured to receive the low voltage input signal VSIG LV and to provide an inverted low voltage signal VSIG INV LV, labeled “VSIG INV LV” in FIG. 2A. The inverted low voltage signal VSIG INV LV inversely corresponds to the low voltage input signal VSIG LV after a delay of signal propagation through a low voltage inverter 224. The inverted low voltage signal VSIG INV LV ranges from the reference potential VSS to the low operating potential VDD LO.

The low voltage inverter 224 may include a low voltage pullup PMOS transistor 224a and a low voltage pulldown NMOS transistor 224b, connected in series between the low operating potential VDD LO and the reference potential VSS, as indicated in FIG. 2A. The low voltage pullup PMOS transistor 224a and the low voltage pulldown NMOS transistor 224b may each be controlled by the low voltage input signal VSIG LV. The low voltage pullup PMOS transistor 224a has a negative transconductance, and the low voltage pulldown NMOS transistor 224b has a positive transconductance. The low voltage pullup PMOS transistor 224a and the low voltage pulldown NMOS transistor 224b may be structured to operate between the low operating potential VDD LO and the reference potential VSS, which may have shorter channel lengths and thinner gate dielectric layers than high voltage transistors, that is, transistors structured to operate between the high operating potential VDD HI and the reference potential VSS. The low voltage transistors may advantageously have higher switching speeds than the high voltage transistors, as a result of the shorter channel lengths. A drain of the low voltage pullup PMOS transistor 224a is connected to a drain of the low voltage pulldown NMOS transistor 224b. The drains of the low voltage pullup PMOS transistor 224a and the low voltage pulldown NMOS transistor 224b may provide the inverted low voltage signal VSIG INV LV, as indicated in FIG. 2A.

The level shifter 202 includes a second buffer 216 structured to receive the inverted low voltage signal VSIG INV LV as an input. The second buffer 216 includes a second cutoff PMOS transistor 222, a second pullup PMOS transistor 218, a second pulldown NMOS transistor 220, and a buffer enable NMOS transistor 234 connected in series between the high operating potential VDD HI and the reference potential VSS. The second pullup PMOS transistor 218 and the second pulldown NMOS transistor 220 are structured to be controlled by the inverted low voltage signal VSIG INV LV. The second cutoff PMOS transistor 222 is structured to be controlled by an inverted high voltage signal VSIG INV HV, labeled “VSIG INV HV” in FIG. 2A and FIG. 2B. The inverted high voltage signal VSIG INV HV ranges from the reference potential VSS to the high operating potential VDD HI, and inversely corresponds to the high voltage output signal VSIG HV after a delay of signal propagation through the high voltage inverter 226. The buffer enable NMOS transistor 234 is structured to be controlled by an enable signal ENABLE, labeled “ENABLE” in FIG. 2A and FIG. 2B. The enable signal ENABLE ranges from the reference potential VSS to the high operating potential VDD HI, and is set to the high operating potential VDD HI for normal operation of the level shifter 202. The enable signal ENABLE may be set to the reference potential VSS during startup of the semiconductor device 200, during assertion of sleep condition, or on other occasions. A drain of the second pullup PMOS transistor 218 is connected to a drain of the second pulldown NMOS transistor 220; the drains of the second pullup PMOS transistor 218 and the second pulldown NMOS transistor 220 are connected to the high voltage output signal VSIG HV of the level shifter 202.

The semiconductor device 200 of this example further includes a reset pullup PMOS transistor 236 connected between the high operating potential VDD HI and the high voltage output signal VSIG HV of the level shifter 202. The reset pullup PMOS transistor 236 is structured to be controlled by a reset signal RESET, labeled “RESET” in FIG. 2A. The reset signal RESET ranges from the reference potential VSS to the high operating potential VDD HI, and is set to the high operating potential VDD HI for normal operation of the level shifter 202 and during the sleep mode. The reset signal RESET may be set to the reference potential VSS during startup of the semiconductor device 200, or on other occasions.

In some implementations it may be advantageous to arrange the first pullup PMOS transistor 206, the first pulldown NMOS transistor 208 and the first cutoff NMOS transistor 210 as illustrated, in which the first cutoff NMOS transistor 210 is connected between the first pulldown NMOS transistor 208 and the reference potential VSS. In an alternate configuration, in which the first pulldown NMOS transistor 208 is connected between the first cutoff NMOS transistor 210 and the reference potential VSS, it is possible under some circumstances that a transition of VCO DEV HV from a low state to a high state will lead to charge sharing on the circuit node to which the gate of the rising edge pullup PMOS transistor 212 is connected.

The semiconductor device 200 of this example also includes the high voltage inverter 226. The high voltage inverter 226 is structured to provide the inverted high voltage signal VSIG INV HV. The high voltage inverter 226 may include a high voltage inverter pullup PMOS transistor 226a and a high voltage inverter pulldown NMOS transistor 226b, connected in series between the high operating potential VDD HI and the reference potential VSS, as indicated in FIG. 2A. The high voltage inverter pullup PMOS transistor 226a and the high voltage inverter pulldown NMOS transistor 226b may each be controlled by the high voltage output signal VSIG HV. The high voltage inverter pullup PMOS transistor 226a has a negative transconductance, and the high voltage inverter pulldown NMOS transistor 226b has a positive transconductance. The high voltage inverter pullup PMOS transistor 226a and the high voltage inverter pulldown NMOS transistor 226b may be structured to operate between the high operating potential VDD HI and the reference potential VSS, to provide the inverted high voltage signal VSIG INV HV with a desired range between the high operating potential VDD HI and the reference potential VSS. The high voltage inverter 226 may be free of low voltage transistors, advantageously reducing an area of the high voltage inverter 226. A drain of the high voltage inverter pullup PMOS transistor 226a is connected to a drain of the high voltage inverter pulldown NMOS transistor 226b; the drains of the high voltage inverter pullup PMOS transistor 226a and the high voltage inverter pulldown NMOS transistor 226b may provide the inverted high voltage signal VSIG INV HV, as indicated in FIG. 2A.

The semiconductor device 200 of this example further includes the high voltage delay buffer 228, structured to provide the delayed high voltage cutoff signal VCO DEL HV. The high voltage delay buffer 228 may include two delay stages. The high voltage delay buffer 228 may include a high voltage NAND gate 228a and a high voltage delay inverter 228b. The high voltage NAND gate 228a includes a signal-controlled pullup PMOS transistor 228c and an enable-controlled pullup PMOS transistor 228d, connected in parallel to the high operating potential VDD HI. The signal-controlled pullup PMOS transistor 228c is structured to be controlled by the inverted high voltage signal VSIG INV HV, and the enable-controlled pullup PMOS transistor 228d is structured to be controlled by the enable signal ENABLE. The high voltage NAND gate 228a also includes a signal-controlled pulldown NMOS transistor 228e and an enable-controlled pulldown NMOS transistor 228f, connected in series between the reference potential VSS and drains of the signal-controlled pullup PMOS transistor 228c and the enable-controlled pullup PMOS transistor 228d, as indicated in FIG. 2B. The signal-controlled pulldown NMOS transistor 228e is structured to be controlled by the inverted high voltage signal VSIG INV HV, and the enable-controlled pulldown NMOS transistor 228f is structured to be controlled by the enable signal ENABLE. A drain of the signal-controlled pulldown NMOS transistor 228e may be connected to the drains of the signal-controlled pullup PMOS transistor 228c and the enable-controlled pullup PMOS transistor 228d, and a source of the enable-controlled pulldown NMOS transistor 228f may be connected to the reference potential VSS, as indicated in FIG. 2B. Alternately, the signal-controlled pulldown NMOS transistor 228e and the enable-controlled pulldown NMOS transistor 228f may be exchanged, so that a drain of the enable-controlled pulldown NMOS transistor 228f may be connected to the drains of the signal-controlled pullup PMOS transistor 228c and the enable-controlled pullup PMOS transistor 228d, and a source of the signal-controlled pulldown NMOS transistor 228e may be connected to the reference potential VSS.

The high voltage delay inverter 228b may include a delay pullup transistor 228g and a delay pulldown transistor 228h, connected in series between the high operating potential VDD HI and the reference potential VSS, as indicated in FIG. 2B. The delay pullup transistor 228g and the delay pulldown transistor 228h may each be controlled by the drains of the signal-controlled pullup PMOS transistor 228c and the enable-controlled pullup PMOS transistor 228d, and by the series combination of the signal-controlled pulldown NMOS transistor 228e and the enable-controlled pulldown NMOS transistor 228f. Drains of the delay pullup transistor 228g and the delay pulldown transistor 228h may be connected to each other; the drains of the delay pullup transistor 228g and the delay pulldown transistor 228h may provide the delayed high voltage cutoff signal VCO DEL HV. The signal-controlled pullup PMOS transistor 228c, the enable-controlled pullup PMOS transistor 228d, the signal-controlled pulldown NMOS transistor 228e, the enable-controlled pulldown NMOS transistor 228f, the delay pullup transistor 228g, and the delay pulldown transistor 228h may be structured to operate between the high operating potential VDD HI and the reference potential VSS, to provide the delayed high voltage cutoff signal VCO DEL HV with a desired range between the high operating potential VDD HI and the reference potential VSS. The high voltage delay buffer 228 may be free of low voltage transistors, advantageously reducing an area of the high voltage delay buffer 228. Other circuit configurations for the high voltage delay buffer 228 are within the scope of this example.

The semiconductor device 200 of this example also includes a sleep signal inverter 230 structured to receive a sleep signal SLEEP, labeled “SLEEP” in FIG. 2B, and structured to provide an inverted sleep signal INV SLEEP, labeled “INV SLEEP” in FIG. 2B. The sleep signal SLEEP and the inverted sleep signal INV SLEEP may range from the reference potential VSS to the high operating potential VDD HI. The inverted sleep signal INV SLEEP inversely corresponds to the sleep signal SLEEP after a delay of signal propagation through the sleep signal inverter 230. The sleep signal inverter 230 may include a sleep pullup PMOS transistor 230a, and a sleep pulldown NMOS transistor 230b, connected in series between the high operating potential VDD HI and the reference potential VSS, as indicated in FIG. 2B. The sleep pullup PMOS transistor 230a and the sleep pulldown NMOS transistor 230b may each be controlled by the sleep signal SLEEP. The sleep pullup PMOS transistor 230a and the sleep pulldown NMOS transistor 230b may be structured to operate between the high operating potential VDD HI and the reference potential VSS, to provide the inverted sleep signal INV SLEEP with a desired range between the high operating potential VDD HI and the reference potential VSS. A drain of the sleep pullup PMOS transistor 230a is connected to a drain of the sleep pulldown NMOS transistor 230b; the drains of the sleep pullup PMOS transistor 230a and the sleep pulldown NMOS transistor 230b may provide the inverted sleep signal INV SLEEP, as indicated in FIG. 2B.

The semiconductor device 200 of this example further includes a sleep latch 232. The sleep latch 232 of this example includes a sleep pullup leg 232a connected between the high operating potential VDD HI and the high voltage output signal VSIG HV. The sleep latch 232 of this example includes a sleep pulldown leg 232b connected between the high voltage output signal VSIG HV and the reference potential VSS.

The sleep pullup leg 232a includes the second cutoff PMOS transistor 222 connected in series with a sleep isolation PMOS transistor 232c. The second cutoff PMOS transistor 222 is structured to be controlled by the inverted high voltage signal VSIG INV HV, as disclosed in reference to the second buffer 216. The sleep isolation PMOS transistor 232c is structured to be controlled by the inverted sleep signal INV SLEEP. The sleep isolation PMOS transistor 232c may be a high voltage transistor, structured to operate between the high operating potential VDD HI and the reference potential VSS. A drain of the sleep isolation PMOS transistor 232c may be connected to the high voltage output signal VSIG HV, as indicated in FIG. 2B.

The sleep pulldown leg 232b includes a sleep pulldown NMOS transistor 232d connected in series with a sleep isolation NMOS transistor 232e. The sleep pulldown NMOS transistor 232d is structured to be controlled by the inverted high voltage signal VSIG INV HV. The sleep isolation NMOS transistor 232e is structured to be controlled by the sleep signal SLEEP. The sleep pulldown NMOS transistor 232d and the sleep isolation NMOS transistor 232e may be high voltage transistors. A drain of the sleep isolation NMOS transistor 232e may be connected to the high voltage output signal VSIG HV, and a source of the sleep pulldown NMOS transistor 232d may be connected to the reference potential VSS, as indicated in FIG. 2B.

Operation of the semiconductor device 200 of this example includes a rising edge transition of the low voltage input signal VSIG LV, a falling edge transition of the low voltage input signal VSIG LV, a sleep mode, and a reset mode. Operation of the semiconductor device 200 with respect to the enable signal ENABLE, the sleep signal SLEEP, and the reset signal RESET is disclosed. Operation of the semiconductor device 200 is disclosed in reference to FIG. 2A and FIG. 2B. During the rising edge transition and the falling edge transition, the enable signal ENABLE and the reset signal RESET are at the high operating potential VDD HI, and the sleep signal SLEEP is at the reference potential VSS. During the sleep mode, the sleep signal SLEEP and the reset signal RESET are at the high operating potential VDD HI and the enable signal ENABLE is at the reference potential VSS. During the reset mode, the enable signal ENABLE, the reset signal RESET, and the sleep signal SLEEP are all at the reference potential VSS.

Regarding the rising edge, immediately before the rising edge transition, in the first buffer 204, the low voltage input signal VSIG LV is at the reference potential VSS, which causes the first pullup PMOS transistor 206 to be in an ON state and causes the first pulldown NMOS transistor 208 to be in an OFF state, causing a drain of the first pullup PMOS transistor 206 to be at the high operating potential VDD HI. The drain of the first pullup PMOS transistor 206 at the high operating potential VDD HI causes the rising edge pullup PMOS transistor 212 to be in an OFF state.

Immediately before the rising edge transition, the inverted low voltage signal VSIG INV LV is at the low operating potential VDD LO, by operation of the low voltage inverter 224. In the second buffer 216, the inverted low voltage signal VSIG INV LV at the low operating potential VDD LO causes the second pullup PMOS transistor 218 to be in an OFF state or a near OFF state and causes the second pulldown NMOS transistor 220 to be in an ON state or a partial ON state. The enable signal ENABLE at the high operating potential VDD HI causes the buffer enable NMOS transistor 234 to be in an ON state. The rising edge pullup PMOS transistor 212 in the OFF state, the second pullup PMOS transistor 218 in the OFF state or the near OFF state, the second pulldown NMOS transistor 220 in the ON state or the partial ON state, and the buffer enable NMOS transistor 234 in the ON state causes the high voltage output signal VSIG HV of the level shifter 202 to be at the reference potential VSS. The reset signal RESET at the high operating potential VDD HI causes the reset pullup PMOS transistor 236 to be in an OFF state.

Immediately before the rising edge transition, the high voltage output signal VSIG HV at the reference potential VSS causes the inverted high voltage signal VSIG INV HV to be at the high operating potential VDD HI, by operation of the high voltage inverter 226. The inverted high voltage signal VSIG INV HV and the enable signal ENABLE both at the high operating potential VDD HI causes the delayed high voltage cutoff signal VCO DEL HV to be at the high operating potential VDD HI, by operation of the high voltage delay buffer 228. The delayed high voltage cutoff signal VCO DEL HV at the high operating potential VDD HI causes the first cutoff NMOS transistor 210 to be in an ON state, and causes the reset PMOS transistor 214 to be in an OFF state. The inverted high voltage signal VSIG INV HV at the high operating potential VDD HI causes the second cutoff PMOS transistor 222 to be in an OFF state.

Immediately before the rising edge transition, the sleep signal SLEEP at the reference potential VSS causes the inverted sleep signal INV SLEEP to be at the high operating potential VDD HI, by operation of the sleep signal inverter 230. In the sleep latch 232, the sleep signal SLEEP at the reference potential VSS causes the sleep isolation NMOS transistor 232e to be in an OFF state, and the inverted sleep signal INV SLEEP at the high operating potential VDD HI causes the sleep isolation PMOS transistor 232c to be in an OFF state, isolating the high voltage output signal VSIG HV of the level shifter 202 from the high operating potential VDD HI through the sleep pullup leg 232a, and isolating the high voltage output signal VSIG HV from the reference potential VSS through the sleep pulldown leg 232b.

When the low voltage input signal VSIG LV executes the rising edge transition, the low voltage input signal VSIG LV transitions from the reference potential VSS to the low operating potential VDD LO, causing the first pullup PMOS transistor 206 to transition to an OFF state or a near OFF state, and causing the first pulldown NMOS transistor 208 to transition to an ON state or a partial ON state. The first cutoff NMOS transistor 210 is still in the ON state, so the first pullup PMOS transistor 206 transitioning to the OFF state or the near OFF state, and the first pulldown NMOS transistor 208 transitioning to the ON state or the partial ON state causes a drain of the first pulldown NMOS transistor 208 to transition to the reference potential VSS, which causes the rising edge pullup PMOS transistor 212 to transition to an ON state, which causes the drain of the rising edge pullup PMOS transistor 212 to transition from the reference potential VSS to the high operating potential VDD HI. Having the drain of the first pulldown NMOS transistor 208 connected to a single gate of a transistor, namely the rising edge pullup PMOS transistor 212, may accrue the advantage of speed disclosed in reference to the level shifter 102 of FIG. 1.

The rising edge transition causes the low voltage inverter 224 to transition the inverted low voltage signal VSIG INV LV from the low operating potential VDD LO to the reference potential VSS, causing the second pullup PMOS transistor 218 to transition to an ON state, and causing the second pulldown NMOS transistor 220 to transition to an OFF state. The buffer enable NMOS transistor 234 remains in the ON state. The second cutoff PMOS transistor 222 still in the OFF state and the second pulldown NMOS transistor 220 transitioning to the OFF state causes the drain of the second pulldown NMOS transistor 220 and the drain of the second pullup PMOS transistor 218 to present a high impedance, so that at the high voltage output signal VSIG HV of the level shifter 202 is driven by the drain of the rising edge pullup PMOS transistor 212 to transition from the reference potential VSS to the high operating potential VDD HI.

The high voltage output signal VSIG HV transitioning to the high operating potential VDD HI causes the inverted high voltage signal VSIG INV HV to transition to the reference potential VSS, by operation of the high voltage inverter 226. The inverted high voltage signal VSIG INV HV transitioning to the reference potential VSS causes the second cutoff PMOS transistor 222 to transition to an ON state. The second cutoff PMOS transistor 222 and the second pullup PMOS transistor 218 both in ON states and the second pulldown NMOS transistor 220 in the OFF state causes the drain of the second pullup PMOS transistor 218 to transition to the high operating potential VDD HI, reinforcing the potential of the high operating potential VDD HI on the drain of the rising edge pullup PMOS transistor 212.

The inverted high voltage signal VSIG INV HV transitioning to the reference potential VSS causes the delayed high voltage cutoff signal VCO DEL HV to transition to the reference potential VSS, by operation of the high voltage delay buffer 228, after a signal propagation delay through the high voltage NAND gate 228a and the high voltage delay inverter 228b. The delayed high voltage cutoff signal VCO DEL HV transitioning to the reference potential VSS causes the reset PMOS transistor 214 to transition to an ON state, which causes the drain of the reset PMOS transistor 214 to transition to the high operating potential VDD HI, which in turn causes the rising edge pullup PMOS transistor 212 to transition to the OFF state, isolating the high voltage output signal VSIG HV of the level shifter 202 from the high operating potential VDD HI through the rising edge pullup PMOS transistor 212.

The delayed high voltage cutoff signal VCO DEL HV transitioning to the reference potential VSS also causes the first cutoff NMOS transistor 210 to transition to an OFF state, which advantageously reduces current through the first pulldown NMOS transistor 208. The drain of the reset PMOS transistor 214 transitioning to the high operating potential VDD HI, in combination with the first cutoff NMOS transistor 210 transitioning to the OFF state, advantageously resets the drain of the first pulldown NMOS transistor 208 to the high operating potential VDD HI, to be ready for the next rising edge transition in the low voltage input signal VSIG LV.

Regarding the falling edge transition, the low voltage input signal VSIG LV transitions from the low operating potential VDD LO to the reference potential VSS, causing the first pullup PMOS transistor 206 to transition to the ON state, and causing the first pulldown NMOS transistor 208 to transition to the OFF state. The first cutoff NMOS transistor 210 still in the OFF state, the first pullup PMOS transistor 206 transitioning to the ON state, and the first pulldown NMOS transistor 208 transitioning to the OFF state maintains the drain of the first pullup PMOS transistor 206 at the high operating potential VDD HI.

The falling edge transition causes the low voltage inverter 224 to transition the inverted low voltage signal VSIG INV LV from the reference potential VSS to the low operating potential VDD LO, causing the second pullup PMOS transistor 218 to transition to the OFF state or the near OFF state and causes the second pulldown NMOS transistor 220 to transition to the ON state or the partial ON state. The second cutoff PMOS transistor 222 is in the ON state, because the delayed high voltage cutoff signal VCO DEL HV is still at the reference potential VSS. The buffer enable NMOS transistor 234 remains in the ON state. The second cutoff PMOS transistor 222 in the ON state, the second pullup PMOS transistor 218 transitioning to the OFF state or the near OFF state, the second pulldown NMOS transistor 220 transitioning to the ON state or the partial ON state, and the buffer enable NMOS transistor 234 in the ON state causes the drain node of the second pulldown NMOS transistor 220 to transition to near the reference potential VSS.

The drain of the first pullup PMOS transistor 206 at the high operating potential VDD HI maintains the rising edge pullup PMOS transistor 212 in the OFF state, thus maintaining isolation of the high voltage output signal VSIG HV of the level shifter 202 through the rising edge pullup PMOS transistor 212. The high voltage output signal VSIG HV of the level shifter 202 is thus driven by the drain node of the second pulldown NMOS transistor 220 to transition to the reference potential VSS. The reset signal RESET remains at the high operating potential VDD HI, causing the reset pullup PMOS transistor 236 to remain in the OFF state, isolating the high voltage output signal VSIG HV of the level shifter 202 from the high operating potential VDD HI through the reset pullup PMOS transistor 236.

The high voltage output signal VSIG HV transitioning to the reference potential VSS causes the inverted high voltage signal VSIG INV HV to transition to the high operating potential VDD HI, by operation of the high voltage inverter 226, causing the second cutoff PMOS transistor 222 to transition to the OFF state. The second cutoff PMOS transistor 222 in the OFF state, the second pullup PMOS transistor 218 in the OFF state or the near OFF state, and the second pulldown NMOS transistor 220 and the buffer enable NMOS transistor 234 both in the ON states stabilizes the drain node of the second pulldown NMOS transistor 220 at the reference potential VSS.

The inverted high voltage signal VSIG INV HV transitioning to the high operating potential VDD HI and the enable signal ENABLE at the high operating potential VDD HI causes the delayed high voltage cutoff signal VCO DEL HV to transition to the high operating potential VDD HI after a signal propagation delay through the high voltage delay buffer 228. The delayed high voltage cutoff signal VCO DEL HV transitioning to the high operating potential VDD HI causes the reset PMOS transistor 214 to transition to an OFF state, which provides a high impedance to the drain of the first pulldown NMOS transistor 208, enabling a subsequent rising edge transition in the low voltage input signal VSIG LV. The delayed high voltage cutoff signal VCO DEL HV transitioning to the high operating potential VDD HI also causes the first cutoff NMOS transistor 210 to transition to an ON state, enabling a subsequent rising edge transition in the low voltage input signal VSIG LV.

In the sleep mode, the sleep signal SLEEP is transitioned from the reference potential VSS to the high operating potential VDD HI, and the enable signal ENABLE is transitioned from the high operating potential VDD HI to the reference potential VSS. The reset signal RESET is maintained at the high operating potential VDD HI during the sleep mode. The sleep signal SLEEP transitioning to the high operating potential VDD HI causes the inverted sleep signal INV SLEEP to transition from the high operating potential VDD HI to the reference potential VSS, by operation of the sleep signal inverter 230. The sleep signal SLEEP transitioning to the high operating potential VDD HI causes the sleep isolation NMOS transistor 232e to transition to an ON state, and the inverted sleep signal INV SLEEP transitioning to the reference potential VSS causes the sleep isolation PMOS transistor 232c to also transition to an ON state. The enable signal ENABLE transitioning to the reference potential VSS causes the delayed high voltage cutoff signal VCO DEL HV to transition to the reference potential VSS, by operation of the high voltage delay buffer 228.

In cases in which the low voltage input signal VSIG LV is at the reference potential VSS and thus the high voltage output signal VSIG HV is at the reference potential VSS, the inverted high voltage signal VSIG INV HV is at the high operating potential VDD HI, causing the second cutoff PMOS transistor 222 to be in an OFF state and causing the sleep pulldown NMOS transistor 232d to be in an ON state. The second cutoff PMOS transistor 222 in the OFF state isolates the high voltage output signal VSIG HV from the high operating potential VDD HI through the sleep pullup leg 232a. The sleep pulldown NMOS transistor 232d in the ON state and the sleep isolation NMOS transistor 232e in the ON state connects the high voltage output signal VSIG HV to the reference potential VSS through the sleep pulldown leg 232b, causing the high voltage output signal VSIG HV to be latched at the reference potential VSS. If the low voltage input signal VSIG LV subsequently transitions to the low operating potential VDD LO while the sleep signal SLEEP is held at the high operating potential VDD HI, the high voltage output signal VSIG HV remains at the reference potential VSS, because the delayed high voltage cutoff signal VCO DEL HV at the reference potential VSS causes the first cutoff NMOS transistor 210 to be in the OFF state, stopping operation of the first buffer 204. The enable signal ENABLE at the reference potential VSS causes the buffer enable NMOS transistor 234 and the rising edge pullup PMOS transistor 212 to both be in the OFF states, isolating the high voltage output signal VSIG HV from the high operating potential VDD HI through the rising edge pullup PMOS transistor 212. The enable signal ENABLE at the reference potential VSS causes the buffer enable NMOS transistor 234 to be in the OFF state, and the inverted high voltage signal VSIG INV HV at the high operating potential VDD HI causes second cutoff PMOS transistor 222 to be in the OFF state, stopping operation of the second buffer 216. Thus, the sleep pulldown leg 232b and the sleep pullup leg 232a are structured to maintain the high voltage output signal VSIG HV at the reference potential VSS while the sleep signal SLEEP is asserted at the high operating potential VDD HI when the low voltage input signal VSIG LV is at the reference potential VSS.

In cases in which the low voltage input signal VSIG LV is at the low operating potential VDD LO and thus the high voltage output signal VSIG HV is at the high operating potential VDD HI, the inverted high voltage signal VSIG INV HV is at the reference potential VSS, causing the second cutoff PMOS transistor 222 to be in an ON state and causing the sleep pulldown NMOS transistor 232d to be in an OFF state. The sleep pulldown NMOS transistor 232d in the OFF state isolates the high voltage output signal VSIG HV from the reference potential VSS through the sleep pulldown leg 232b. The second cutoff PMOS transistor 222 in the ON state and the sleep isolation PMOS transistor 232c in the ON state connects the high voltage output signal VSIG HV to the high operating potential VDD HI through the sleep pullup leg 232a, causing the high voltage output signal VSIG HV to be latched at the high operating potential VDD HI. If the low voltage input signal VSIG LV subsequently transitions to the reference potential VSS while the sleep signal SLEEP is held at the high operating potential VDD HI, the high voltage output signal VSIG HV remains at the high operating potential VDD HI, because the buffer enable NMOS transistor 234 in the OFF state stops operation of the second buffer 216. Thus, the sleep pulldown leg 232b and the sleep pullup leg 232a are structured to maintain the high voltage output signal VSIG HV at the high operating potential VDD HI while the sleep signal SLEEP is asserted at the high operating potential VDD HI when the low voltage input signal VSIG LV is at the low operating potential VDD LO.

Regarding the reset mode, the enable signal ENABLE at the reference potential VSS causes the buffer enable NMOS transistor 234 to be in the OFF state. The sleep signal SLEEP at the reference potential VSS disables the sleep latch 232. The reset signal RESET at the reference potential VSS causes the reset pullup PMOS transistor 236 to be in the ON state, which causes the high voltage output signal VSIG HV to be held at the high operating potential VDD HI, regardless of the value of the low voltage input signal VSIG LV.

In alternate versions of this example, the high voltage delay buffer 228 may include more than two logic gates in its signal propagation path. In alternate versions of this example, the first cutoff NMOS transistor 210 may be connected between the first pullup PMOS transistor 206 and the first pulldown NMOS transistor 208. In alternate versions of this example, the second cutoff PMOS transistor 222 may be connected between the second pullup PMOS transistor 218 and the second pulldown NMOS transistor 220.

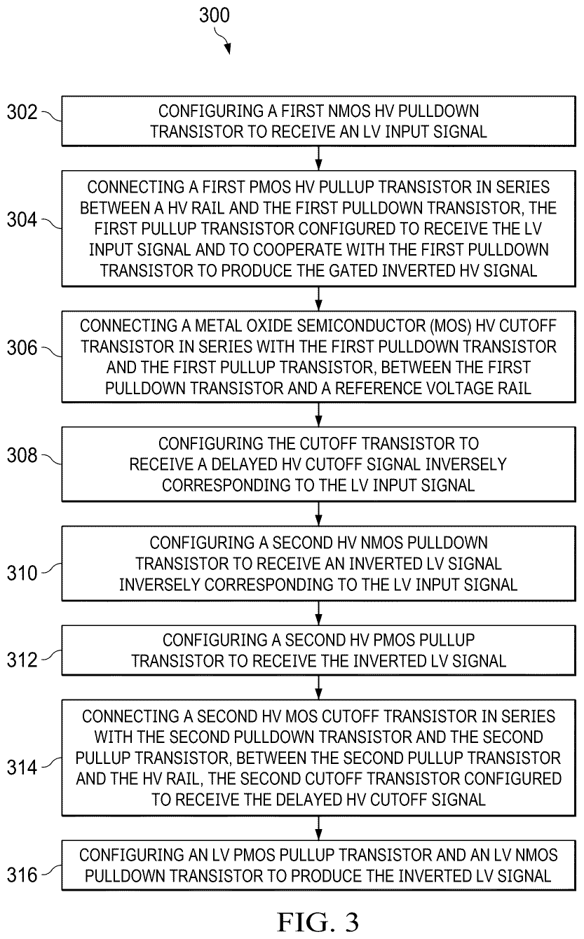

FIG. 3 is a flowchart of a method of forming a semiconductor device having an example low voltage-to-high voltage level shifter. The level shifter is structured to receive a low voltage (LV) input signal and output a high voltage (HV) output signal corresponding to the LV input signal. The level shifter includes a first buffer structured to produce an inverted HV signal inversely corresponding to the LV input signal.

The method 300 includes step 302: configuring a first NMOS HV pulldown transistor of the first buffer to receive the LV input signal. Step 302 may include forming one or more interconnects, vias, and/or contacts to connect a gate of the first NMOS HV pulldown transistor to a circuit structured to provide the LV input signal.

The method 300 includes step 304: connecting a first PMOS HV pullup transistor of the first buffer in series between an HV rail and the first NMOS HV pulldown transistor. Step 304 may include forming one or more interconnects, vias, and/or contacts to connect a source of the first PMOS HV pullup transistor to the HV rail. Step 304 may include forming one or more interconnects, vias, and/or contacts to connect a drain of the first PMOS HV pullup transistor to a drain of the first NMOS HV pulldown transistor. The first PMOS HV pullup transistor is structured to receive the LV input signal and to cooperate with the pulldown transistor to produce the inverted HV signal. Step 304 may include forming one or more interconnects, vias, and/or contacts to connect a gate of the first PMOS HV pullup transistor to the circuit structured to provide the LV input signal.

The method 300 includes step 306: connecting a first MOS HV cutoff transistor of the first buffer in series with the first NMOS HV pulldown transistor and the first PMOS HV pullup transistor, between the first NMOS HV pulldown transistor and a reference voltage rail. Step 306 may include forming one or more interconnects, vias, and/or contacts to connect a source of the first MOS HV cutoff transistor to the reference voltage rail. Step 306 may include forming one or more interconnects, vias, and/or contacts to connect a drain of the first MOS HV cutoff transistor to a source of the first NMOS HV pulldown transistor.

The method 300 includes step 308: configuring the first MOS HV cutoff transistor to receive a delayed HV cutoff signal inversely corresponding to the LV input signal. Step 308 may include forming one or more interconnects, vias, and/or contacts to connect a gate of the first MOS HV cutoff transistor to a circuit structured to provide the delayed HV cutoff signal.

The level shifter may include a second buffer. The method 300 may include step 310: configuring a second HV NMOS pulldown transistor of the second buffer to receive an inverted LV signal. The inverted LV signal inversely corresponds to the LV input signal. Step 310 may include forming one or more interconnects, vias, and/or contacts to connect a gate of the second HV NMOS pulldown transistor to a circuit structured to provide the inverted LV signal.

The method 300 may include step 312: configuring a second HV PMOS pullup transistor of the second buffer to receive the inverted LV signal. Step 312 may include forming one or more interconnects, vias, and/or contacts to connect a gate of the second HV PMOS pullup transistor to a circuit structured to provide the inverted LV signal.

The method 300 may include step 314: connecting a second HV MOS cutoff transistor of the second buffer in series with the second HV NMOS pulldown transistor and the second HV PMOS pullup transistor. The second HV MOS cutoff transistor is connected between the second HV PMOS pullup transistor and the HV rail. The second HV MOS cutoff transistor is structured to receive a delayed HV cutoff signal. Step 314 may include forming one or more interconnects, vias, and/or contacts to connect a source of the second HV MOS cutoff transistor to the HV rail. Step 314 may include forming one or more interconnects, vias, and/or contacts to connect a drain of the second HV MOS cutoff transistor to a source of the second HV PMOS pullup transistor. Step 314 may include forming one or more interconnects, vias, and/or contacts to connect a gate of the second HV MOS cutoff transistor to a circuit structured to provide the delayed HV cutoff signal.

The semiconductor device may include a low voltage inverter. The low voltage inverter is structured to receive the LV input signal, and to provide the inverted LV signal. The method 300 may include step 316: configuring an LV PMOS pullup transistor of the low voltage inverter and an LV NMOS pulldown transistor of the low voltage inverter to produce the inverted LV signal. Step 316 may include forming the LV PMOS pullup transistor to have a thinner gate dielectric layer than either the first PMOS HV pullup transistor or the second PMOS HV pullup transistor. Step 316 may include forming the LV NMOS pulldown transistor to have a thinner gate dielectric layer than either the first NMOS HV pulldown transistor or the second NMOS HV pulldown transistor.

Various features of the examples disclosed herein may be combined in other manifestations of example semiconductor devices. For example, the semiconductor device 100 of FIG. 1 may include a sleep latch similar to the sleep latch 232 of FIG. 2B. The semiconductor device 100 of FIG. 1 may include a reset pullup transconductor coupled between the high operating potential VDD HI and the high voltage output signal VSIG HV of the level shifter 102, analogous to the reset pullup PMOS transistor 236 of FIG. 2A.

While various examples of the present disclosure have been described above, it should be understood that they have been presented by way of example only and not limitation. Numerous changes to the disclosed examples can be made in accordance with the disclosure herein without departing from the spirit or scope of the disclosure. Thus, the breadth and scope of the present disclosure should not be limited by any of the above described examples. Rather, the scope of the disclosure should be defined in accordance with the following claims and their equivalents.

What is claimed is:

1. A semiconductor device, comprising:
a low voltage-to-high voltage level shifter structured to receive a low voltage input signal and provide a high voltage output signal, the low voltage-to-high voltage level shifter including a buffer, the buffer including:
a pullup transconductor structured to be controlled by the low voltage input signal;
a pulldown transconductor structured to be controlled by the low voltage input signal; and
a cutoff transconductor structured to be controlled by a delayed cutoff signal; wherein:
the delayed cutoff signal inversely corresponds to the low voltage input signal; and
the pullup transconductor, the pulldown transconductor, and the cutoff transconductor are connected in series.

2. The semiconductor device of claim 1, wherein the cutoff transconductor is connected between the pulldown transconductor and a reference power rail.

3. The semiconductor device of claim 1, wherein:
the buffer is a first buffer;
the pullup transconductor is a first pullup transconductor;
the pulldown transconductor is a first pulldown transconductor;
the cutoff transconductor is a first cutoff transconductor; and
the delayed cutoff signal is a first delayed cutoff signal;
and further including:
a second buffer, the second buffer including:
a second pullup transconductor structured to be controlled by an inverted low voltage signal, wherein the inverted low voltage signal inversely corresponds to the low voltage input signal;
a second pulldown transconductor structured to be controlled by the inverted low voltage signal; and
a second cutoff transconductor structured to be controlled by a second delayed cutoff signal; wherein:
the second delayed cutoff signal inversely corresponds to the low voltage input signal; and
the second pullup transconductor, the second pulldown transconductor, and the second cutoff transconductor are connected in series.

4. The semiconductor device of claim 1, further including a reset transconductor connected to an output of the buffer, the reset transconductor having an opposite transconductance from the cutoff transconductor, the reset transconductor being structured to be controlled by a delayed reset signal corresponding to the delayed cutoff signal.

5. The semiconductor device of claim 3, further including a rising edge pullup transconductor connected to an output of the low voltage-to-high voltage level shifter, the rising edge pullup transconductor being structured to be controlled by an output of the first buffer.

6. The semiconductor device of claim 3, further including a first power rail and a reference power rail, wherein the first cutoff transconductor is connected to the reference power rail, and the second cutoff transconductor is connected to the first power rail.

7. The semiconductor device of claim 3, further including a low voltage inverter structured to receive the low voltage input signal and structured to provide the inverted low voltage signal, the low voltage inverter being structured to operate at a lower potential than the first buffer and the second buffer.

8. The semiconductor device of claim 1, further including a high voltage inverter structured to receive the high voltage output signal and output an inverted high voltage signal, the inverted high voltage signal inversely corresponding to the high voltage output signal.

9. The semiconductor device of claim 1, further including a delay buffer structured to receive an inverted signal and provide a delayed output signal, wherein the inverted signal inversely corresponds to the high voltage output signal.

10. The semiconductor device of claim 3, wherein:
the first pullup transconductor has a negative transconductance;
the first pulldown transconductor has a positive transconductance;
the first cutoff transconductor has a positive transconductance;
the second pullup transconductor has a negative transconductance;
the second pulldown transconductor has a positive transconductance; and
the second cutoff transconductor has a negative transconductance.

11. The semiconductor device of claim 3, wherein the low voltage-to-high voltage level shifter further includes a sleep pulldown leg in series with a sleep pullup leg; wherein:
the sleep pulldown leg is structured to receive a sleep signal;
the sleep pulldown leg is structured to receive an inverted input signal, the inverted input signal inversely corresponding to the high voltage output signal;
the sleep pullup leg is structured to receive an inverted sleep signal, the inverted sleep signal inversely corresponding to the sleep signal;
the sleep pullup leg is structured to receive the inverted input signal; and
the sleep pulldown leg and the sleep pullup leg are structured to maintain the high voltage output signal while the sleep signal is asserted.

12. The semiconductor device of claim 3, wherein:
the first pullup transconductor is a first pullup p-channel metal oxide semiconductor (PMOS) transistor;
the first pulldown transconductor is a first pulldown n-channel metal oxide semiconductor (NMOS) transistor;
the first cutoff transconductor is a first cutoff NMOS transistor;
the second pullup transconductor is a second pullup PMOS transistor;
the second pulldown transconductor is a second pulldown NMOS transistor; and
the second cutoff transconductor is a second cutoff PMOS transistor.

13. A semiconductor device, comprising:
a low voltage-to-high voltage level shifter structured to receive a low voltage input signal and provide a high voltage output signal, the low voltage-to-high voltage level shifter including a first buffer, including:
a pulldown n-channel metal oxide semiconductor (NMOS) transistor structured to receive the low voltage input signal;
a pullup p-channel metal oxide semiconductor (PMOS) transistor structured to receive the low voltage input signal; and
a cutoff metal oxide semiconductor (MOS) transistor structured to receive a delayed cutoff signal; wherein:
the delayed cutoff signal inversely corresponds to the low voltage input signal; and
the pullup PMOS transistor, the pulldown NMOS transistor, and the cutoff MOS transistor are connected in series between a first power rail and a reference voltage rail.

14. The semiconductor device of claim 13, wherein:
the pullup PMOS transistor is a first pullup PMOS transistor;
the pulldown NMOS transistor is a first pulldown NMOS transistor;
the cutoff MOS transistor is a first cutoff MOS transistor; and
the delayed cutoff signal is a first delayed cutoff signal;
and further including:
a second buffer, including:
a second pullup PMOS transistor structured to receive an inverted low voltage signal, the inverted low voltage signal inversely corresponding to the low voltage input signal;
a second pulldown NMOS transistor structured to receive the inverted low voltage signal; and
a second cutoff MOS transistor structured to receive a second delayed cutoff signal; wherein:
the second delayed cutoff signal inversely corresponds to the low voltage input signal; and
the second pullup PMOS transistor, the second pulldown NMOS transistor, and the second cutoff MOS transistor are connected in series between the first power rail and the reference voltage rail.

15. The semiconductor device of claim 13, further including a reset PMOS transistor connected to an output of the first buffer, the reset PMOS transistor being structured to receive a delayed reset signal corresponding to the delayed cutoff signal.

16. The semiconductor device of claim 13, further including a rising edge pullup PMOS transistor connected to an output of the low voltage-to-high voltage level shifter, the rising edge pullup PMOS transistor being structured to be controlled by an output of the first buffer.

17. The semiconductor device of claim 13, wherein the low voltage-to-high voltage level shifter further includes a sleep pulldown leg in series with a sleep pullup leg; wherein:
the sleep pulldown leg includes a sleep isolation NMOS transistor structured to receive a sleep signal;
the sleep pulldown leg includes a sleep pulldown NMOS transistor structured to receive an inverted input signal, the inverted input signal inversely corresponding to the high voltage output signal;
the sleep pullup leg includes a sleep isolation PMOS transistor structured to receive an inverted sleep signal, the inverted sleep signal inversely corresponding to the sleep signal;
the sleep pullup leg includes a sleep pullup PMOS transistor structured to receive the inverted input signal; and
the sleep pulldown leg and the sleep pullup leg are structured to maintain the high voltage output signal while the sleep signal is asserted.

18. An integrated circuit, comprising:
first and second power rails, the first power rail structured to provide a first operating voltage and the second power rail structured to provide a reference voltage;
a PMOS transistor connected to the first power rail and structured to operate at a first gate voltage, and to receive at its gate an input signal having a maximum voltage less than the gate voltage;
a first NMOS transistor connected between the PMOS transistor and the second power rail, the first NMOS transistor structured to operate at the first gate voltage and to receive the input signal at its gate; and
a second NMOS transistor connected between the first NMOS transistor and the second power rail, the second NMOS transistor structured to operate at the gate voltage and to receive at its gate an input signal having a maximum voltage equal to the gate voltage.

19. A method of forming a semiconductor device, comprising:
forming a low voltage-to-high voltage level shifter to receive a low voltage (LV) input signal and output a high voltage (HV) output signal corresponding to the LV input signal, the low voltage-to-high voltage level shifter including a first buffer configured to produce an inverted HV signal inversely corresponding to the LV input signal, the low voltage-to-high voltage level shifter formed by:
configuring an n-channel metal oxide semiconductor (NMOS) HV pulldown transistor to receive the LV input signal;
connecting an p-channel metal oxide semiconductor (PMOS) HV pullup transistor in series between a HV rail and the pulldown transistor, the pullup transistor configured to receive the LV input signal and to cooperate with the pulldown transistor to produce the inverted HV signal;
connecting a metal oxide semiconductor (MOS) HV cutoff transistor in series with the pulldown transistor and the pullup transistor, between the pulldown transistor and a reference voltage rail; and
configuring the cutoff transistor to receive a delayed HV cutoff signal inversely corresponding to the LV input signal.

20. The method of claim 19, wherein:
the pullup transistor is a first pullup transistor;
the pulldown transistor is a first pulldown transistor;
the cutoff HV MOS transistor is a first cutoff HV MOS transistor; and
the delayed HV cutoff signal is a first delayed HV cutoff signal, and further comprising forming a second buffer by:
configuring a second HV NMOS pulldown transistor to receive an inverted LV signal inversely corresponding to the LV input signal;
configuring a second HV PMOS pullup transistor to receive the inverted HV signal; and
connecting a second HV MOS cutoff transistor in series with the second pulldown transistor and the second pullup transistor, between the second pullup transistor and the reference voltage rail, the second cutoff transistor configured to receive the delayed HV cutoff signal.

21. The method of claim 19, further comprising:
configuring an LV PMOS pullup transistor and an LV NMOS pulldown transistor to produce the inverted LV signal; wherein:
the LV pullup transistor and the HV pulldown transistor have a first gate dielectric thickness; and
the HV pullup transistor, the HV pulldown transistor and the HV cutoff transistor have a greater second gate dielectric thickness.
